(19) United States
(12) Patent Application Publication
(10) Pub. No.: US 2025/0364072 A1
(43) Pub. Date: Nov. 27, 2025

(54) FUSE CIRCUIT HAVING RELIABILITY FOR SOFT ERROR

(71) Applicant: SK hynix Inc., Gyeonggi-do (KR)

(72) Inventor: Dae Joon KIM, Gyeonggi-do (KR)

(21) Appl. No.: 19/021,170

(22) Filed: Jan. 15, 2025

(30) Foreign Application Priority Data
May 22, 2024 (KR) 10-2024-0066529

(51) Int. Cl. G11C 29/00; G11C 5/14

(52) U.S. Cl. CPC G11C 29/787; G11C 5/147; G11C 29/76

(57) ABSTRACT

According to an embodiment of the present disclosure, a fuse circuit includes an input circuit and a latch circuit. The input circuit transmits a fuse data signal to a first node and its inversion to a second node, controlled by a first control signal. The latch circuit, which includes a first inverter, a second inverter, and a clamp circuit, latches these signals. The first inverter outputs the inversion signal from the first node to the second node, while the second inverter outputs the original signal from the second node to the first node. The clamp circuit, connected between a power voltage node and the second node, maintains the signal at the first node at a stable level in response to the control signal and the voltage at the first node.

### CROSS-REFERENCE TO RELATED APPLICATION

The present application claims priority under 35 U.S.C. § 119(a) to Korean patent application number 10-2024-0066529 filed on May 22, 2024, the entire disclosure of which is incorporated by reference herein.

### BACKGROUND

### 1. Field of Invention

Embodiments of the present disclosure generally relate to an electronic device, and more particularly, to a fuse circuit of a semiconductor device.

### 2. Description of Related Art

A dynamic random access memory (DRAM) is configured of a plurality of memory cells arranged in a matrix form. When a defect occurs in even one memory cell among the plurality of memory cells, a semiconductor memory device cannot operate properly and is processed as a defective device.

Therefore, a repair circuit built into the semiconductor device replaces a defective cell with a redundancy cell in order to repair the defective cell. When a row and/or column address signal indicating the defective cell is input, the repair circuit selects a redundancy column/row instead of a defective column/row of a normal memory cell bank. The repair circuit may include fuse circuits in which an address of the defective cell is programmed.

The fuse circuit is affected by a charge generated by exposure to ionizing radiation. Due to emission of radiation, a possibility of a malfunction in which data of a latch in the fuse circuit is inversed increases. This phenomenon is referred to as a soft error. Ionizing radiation may be caused by an alpha ray (α-ray) emitted from a packaging material or a line material. That is, the soft error may mean a phenomenon in which data stored in the latch is changed by a cosmic ray such as an alpha particle. When data inversion occurs frequently in the fuse circuit, a neutron soft error rate (NSER) may increase.

### SUMMARY

An embodiment of the present disclosure provides a fuse circuit with a reduced soft error rate.

According to an embodiment of the disclosure, a fuse circuit may include an input circuit and a latch circuit. The input circuit may transmit, to a first node, a fuse data signal applied to a first input node as a controlled fuse data signal, in response to a first control signal. The input circuit may transmit, to a second node, a fuse data inversion signal applied to a second input node as a controlled fuse data inversion signal. The latch circuit may latch the controlled fuse data signal and the controlled fuse data inversion signal. The latch circuit may include a first inverter, a second inverter, and a clamp circuit. The first inverter may receive the controlled fuse data signal from the first node and output the controlled fuse data inversion signal to the second node. The second inverter may receive the controlled fuse data inversion signal from the second node and output the controlled fuse data signal to the first node. The clamp circuit may be coupled in series between a power voltage node and the second node. The clamp circuit may maintain the controlled fuse data signal of the first node at a constant level in response to the first control signal and a voltage signal of the first node.

According to an embodiment of the disclosure, a fuse circuit may include a first node, a second node, a first inverter, a second inverter and a clamp circuit. The first inverter coupled between the first node and the second node may receive a controlled fuse data signal through the first node, and invert the controlled fuse data signal to output the controlled fuse data inversion signal to the second node. The second inverter coupled between the second node and the first node may receive the controlled fuse data inversion signal through the second node, and invert the controlled fuse data inversion signal to output the controlled fuse data to the first node. The clamp circuit coupled between the first node and the second node may maintain the controlled fuse data signal at a constant level by clamping a level of the controlled fuse data inversion signal.

According to the present technology, a fuse circuit with a reduced soft error rate is provided.

### BRIEF DESCRIPTION OF THE DRAWINGS

FIG. 1 is a diagram illustrating an electronic fuse (e-fuse) and a fuse set according to an embodiment of the present disclosure.

FIG. 2 is a diagram illustrating a fuse circuit according to an embodiment of the present disclosure.

FIG. 3 is a diagram illustrating a detailed configuration of the fuse circuit of FIG. 2 according to an embodiment of the present disclosure.

FIG. 4 is a diagram illustrating soft error occurrence in the fuse circuit of FIG. 3.

FIG. 5 is a timing diagram illustrating the soft error occurrence of FIG. 4.

FIG. 6 is a diagram illustrating a detailed configuration of the fuse circuit of FIG. 2 according to an embodiment of the present disclosure.

FIG. 7 is a diagram illustrating soft error prevention in the fuse circuit of FIG. 6.

FIG. 8 is a timing diagram illustrating soft error prevention of FIG. 7.

### DETAILED DESCRIPTION

Specific structural and functional descriptions of the embodiments according to the concept of the present disclosure disclosed in this specification are merely illustrative for the purpose of describing the embodiments according to the concept of the present disclosure, and embodiments according to the concept of the present disclosure may be implemented in various forms and should not be construed as limited to the embodiments described in this specification.

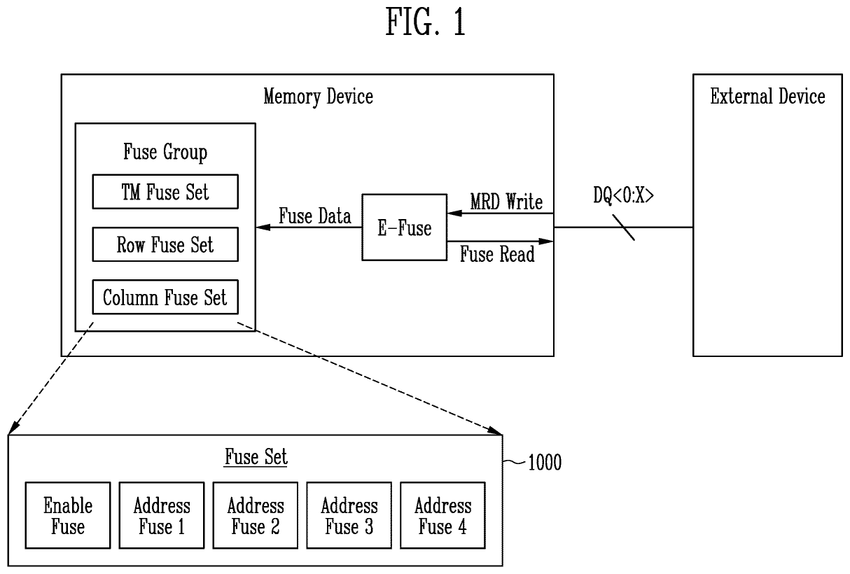

FIG. 1 is a diagram illustrating an electronic fuse (e-fuse) and a fuse set according to an embodiment of the present disclosure.

Referring to FIG. 1, a memory device may include an e-fuse and a fuse group for performing a repair operation on memory cells included in the memory device. The memory device may write memory repair data (MRD) input from an external device through a DQ pin DQ<0:X> to the e-fuse through fuse cutting. The external device may read the data written to the e-fuse and check whether fuse data is normally written to the e-fuse. The MRD may include data for transmitting an address of a defective memory cell. In an embodiment, the memory device may be a dynamic random access memory (DRAM). The e-fuse may include a fuse that stores the fuse data by changing a resistance between a gate and drain/source using a transistor. The e-fuse may write the fuse data in a method of cutting an internal fuse. For example, since a current may not flow through a cut fuse, a drop of a voltage signal applied to the transistor may not occur, and the cut fuse may output a high level of fuse data. Since a current may flow through an uncut fuse, a drop in a voltage signal applied to the transistor may occur, and the uncut fuse may output a low level of fuse data. The e-fuse may transmit the fuse data to the fuse group during booting. The fuse group may include a plurality of fuse sets. For example, the fuse group may include a test mode (TM) fuse set that stores test mode information, a row fuse set that stores row repair address information, and a column fuse set that stores column repair address information.

The fuse set 1000 may indicate at least one fuse set among the plurality of fuse sets included in the fuse group. The fuse set 1000 may include an enable fuse and a plurality of address fuses. The enable fuse may program information on whether the corresponding fuse set 1000 is programming a valid repair address. The plurality of address fuses may include fuse cells for programming each bit of a repair address to program the repair address.

When a row and/or column address signal indicating a defective cell is input to repair the defective cell, the repair circuit may select a redundancy column/row instead of a defective column/row of a normal memory cell bank based on the repair address programmed in the fuse set 1000.

In FIG. 1, when the fuse data input to the enable fuse has a high level, the fuse set 1000 may be in a used state, and the address fuses may be in a state in which the repair address is programmed. When the fuse data input to the enable fuse has a low level, the fuse set 1000 may be in an unused state.

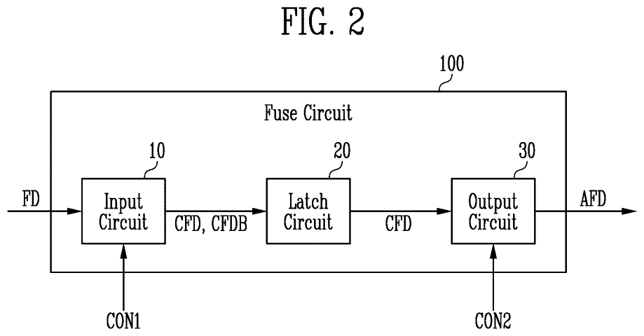

FIG. 2 is a diagram illustrating a fuse circuit 100 according to an embodiment of the present disclosure.

Referring to FIG. 2, the fuse circuit 100 may be a circuit indicating one fuse among the plurality of fuses included in the fuse set 1000 described with reference to FIG. 1. In FIG. 2, the fuse circuit 100 is described based on the fuse circuit being the enable fuse. The address fuse and the enable fuse may be physically the same structure but there is a difference: data stored in the address fuse may be address data, whereas data stored in the enable fuse may be data indicating whether or not the address data stored in the address fuse is used.

The fuse circuit 100 may include an input circuit 10, a latch circuit 20, and an output circuit 30. In response to a first control signal CON1, the input circuit 10 may transmit input fuse data signal FD to the latch circuit 20 as a controlled fuse data signal CFD and a controlled fuse data inversion signal CFDB. The input circuit 10 may include an inverter that inverts the fuse data signal FD and outputs a fuse data inversion signal FDB. The input circuit 10 may generate the controlled fuse data signal CFD and the controlled fuse data inversion signal CFDB based on the fuse data signal FD and the fuse data inversion signal FDB. The latch circuit 20 may store the controlled fuse data signal CFD and the controlled fuse data inversion signal CFDB received from the input circuit 10. The output circuit 30 may output the controlled fuse data signal CFD received from the latch circuit 20 to an outside as an address processed fuse data signal AFD in response to a second control signal CON2. The controlled fuse data signal CFD may include bit data of the repair address.

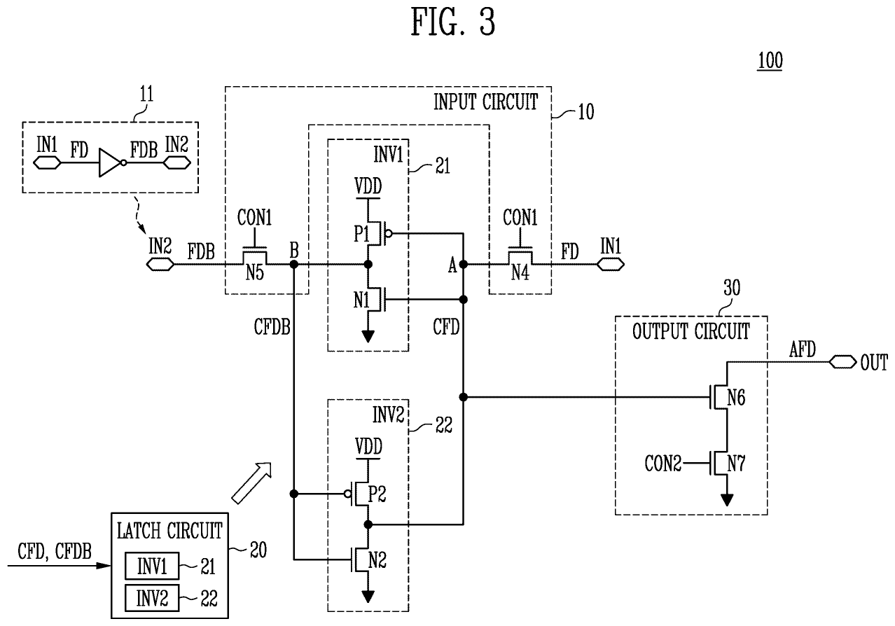

FIG. 3 is a diagram illustrating a detailed configuration of the fuse circuit 100 of FIG. 2 according to an embodiment of the present disclosure.

Referring to FIG. 3, the fuse circuit 100 may include the input circuit 10, the latch circuit 20, and the output circuit 30.

In response to the first control signal CON1, the input circuit 10 may transmit, to a first node A, the fuse data signal FD applied to a first input node IN1 as the controlled fuse data signal CFD, and transmit, to a second node B, the fuse data inversion signal FDB applied to a second input node IN2 as the controlled fuse data inversion signal CFDB. The controlled fuse data signal CFD may be a signal in which the fuse data signal FD is controlled according to the first control signal CON1. The controlled fuse data inversion signal CFDB may be a signal in which the fuse data inversion signal FDB is controlled according to the first control signal CON1.

The input circuit 10 may include an inverter 11 connected between the first input node IN1 and the second input node IN2, a fourth NMOS N4 connected between the first input node IN1 and the first node A, and a fifth NMOS transistor N5 connected between the second input node IN2 and the second node B. The inverter 11 may invert the fuse data signal FD input from the first input node IN1 and output the fuse data inversion signal FDB to the second input node IN2. The fourth NMOS transistor N4 may transmit, to the first node A, the fuse data signal FD applied to the first input node IN1 in response to the first control signal CON1. The fifth NMOS transistor N5 may transmit, to the second node B, the fuse data inversion signal FDB applied to the second input node IN2 as the controlled fuse data inversion signal CFDB in response to the first control signal CON1.

The latch circuit 20 may latch the controlled fuse data signal CFD and the controlled fuse data inversion signal CFDB. The latch circuit 20 may include a first inverter 21 and a second inverter 22 of which input and output terminals are connected to each other in a feedback manner.

The first inverter 21 may receive the controlled fuse data signal CFD from the first node A and output the controlled fuse data inversion signal CFDB to the second node B. The first inverter 21 may include a first PMOS transistor P1 connected between a power voltage node VDD and the second node B, and a first NMOS transistor N1 connected between the second node B and a ground voltage node. Each of a gate terminal of the first PMOS transistor P1 and a gate terminal of the first NMOS transistor N1 may be connected to the first node A.

The second inverter 22 may receive the controlled fuse data inversion signal CFDB from the second node B and output a controlled fuse data signal CFD to the first node A. The second inverter 22 includes a second PMOS transistor P2 connected between the power voltage node VDD and the first node A, and a second NMOS transistor N2 connected between the first node A and the ground voltage node. It may include a MOS transistor N2. Each of the gate terminal of the second PMOS transistor P2 and the gate terminal of the second NMOS transistor N2 may be connected to the second node B.

For example, when a voltage signal of the second node B has a high level, the second NMOS transistor N2 of the second inverter 22 may be turned on. Then, the first node A may become a low level, and thus the first PMOS transistor P1 of the first inverter 21 may be turned on. When the first PMOS transistor P1 is turned on, the voltage signal of the second node B may maintain the high level, and thus high data may be latched.

When the voltage signal of the second node B has a low level, the second PMOS transistor P2 of the second inverter 22 may be turned on. Then, the first node A may become a high level, and thus the first NMOS transistor N1 of the first inverter 21 may be turned on. When the first NMOS transistor N1 is turned on, the voltage signal of the second node B may maintain the low level, and thus low data may be latched.

In response to the second control signal CON2, the output circuit 30 may output, to an output node OUT, the controlled fuse data signal CFD received from the first node A as an address processed fuse data signal AFD. The output circuit 30 may include a sixth NMOS transistor N6 and a seventh NMOS transistor N7 connected in series between the output node OUT and the ground voltage node. A gate terminal of the sixth NMOS transistor N6 may be connected to the first node A, and the second control signal CON2 may be applied to a gate terminal of the seventh NMOS transistor N7. The address processed fuse data signal AFD may be a signal obtained by controlling the controlled fuse data signal CFD according to the second control signal CON2.

When the second control signal CON2 has a high level, the seventh NMOS transistor N7 of the output circuit 30 may be turned on. When a voltage signal of the first node A has a high level, the sixth NMOS transistor N6 may be turned on, and thus a low level of controlled fuse data signal CFD latched in the first node A may be output to the output node OUT as the address processed fuse data signal AFD. When the voltage signal of the first node A has a low level, the sixth NMOS transistor N6 may not be turned on, (i.e., turned off), and thus the existing address processed fuse data signal AFD may be output to the output node OUT.

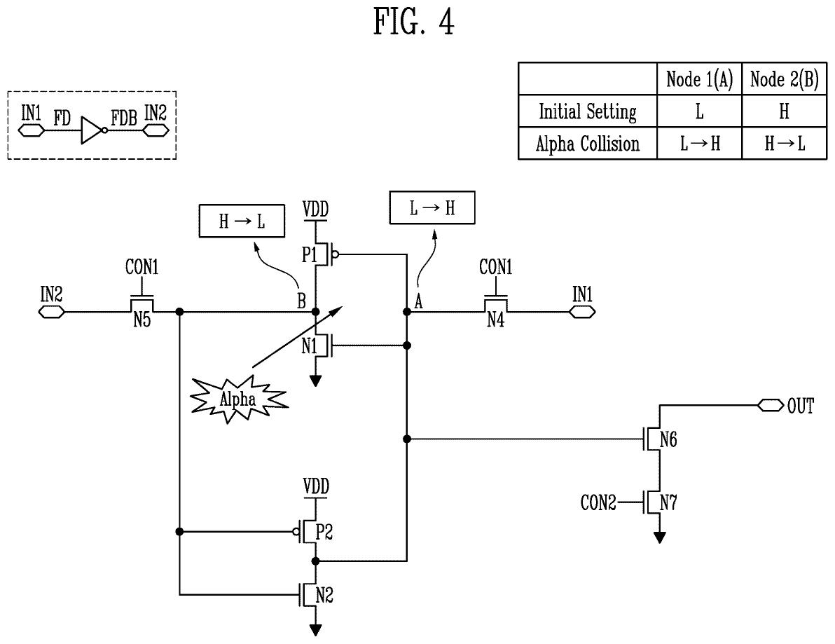

FIG. 4 is a diagram illustrating soft error occurrence in the fuse circuit 100 of FIG. 3.

Referring to FIG. 4, when a fuse data signal FD applied to the first input node IN1 has a low level L, in response to the first control signal CON1, the voltage signal of the first node A may be set to a low level L and the voltage signal of the second node B may be set to a high level H initially. The embodiment is described based on that an alpha particle collides with the first NMOS transistor N1.

When the alpha particle collides with the first NMOS transistor N1, the first NMOS transistor N1 may be momentarily turned on. The second node B may be connected to the ground voltage node, and the voltage signal of the second node B may transition to a low level L. When the voltage signal of the second node B transitions to the low level L, the second PMOS transistor P2 is turned on, and the voltage signal of the first node A transitions to a high level H.

In conclusion, due to the collision of the alpha particle, the voltage signal of the first node A initially transitions from a low level L to a high level H, the voltage signal of the second node B transitions from a high level H to a low level L, and thus a soft error in which the fuse data is flipped occurs.

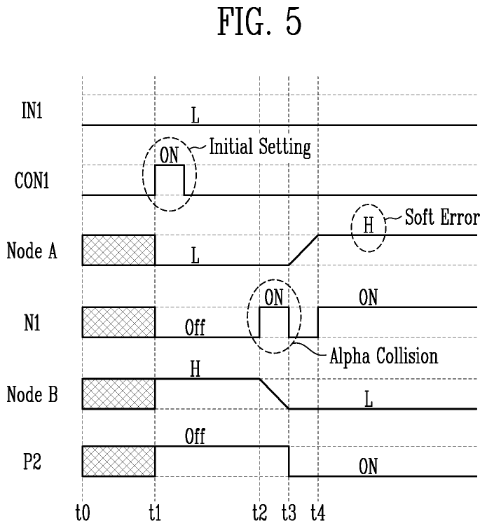

FIG. 5 is a timing diagram illustrating the soft error occurrence of FIG. 4.

Referring to FIG. 5, the soft error occurrence of the fuse circuit in t0 to t4 may be described.

At t0, the fuse data signal applied to the first input node IN1 may have a low level L.

At t1, when the first control signal CON1 is turned on, in response to the first control signal CON1, the voltage signal of the first node A may be set to a low level L and the voltage signal of the second node B may be set to a high level H initially. The low level L may be a ground voltage level and the high level H may be a power voltage level.

At t2, when the alpha particle collides with the first NMOS transistor N1, the first NMOS transistor N1 may be momentarily turned on. The second node B may be connected to the ground voltage node.

In t2 to t3, the voltage signal of the second node B may transition to a low level L.

At t3, since the voltage signal of the second node B has a low level L, the second PMOS transistor P2 may be turned on. The first node A may be connected to the power voltage node.

In t3 to t4, the voltage signal of the first node A may transition to a high level H.

In conclusion, due to the collision of the alpha particle, the voltage signal of the first node A initially transitions from a low level L to a high level H, the voltage signal of the second node B transitions from a high level H to a low level L, and thus a soft error in which the fuse data is flipped occurs.

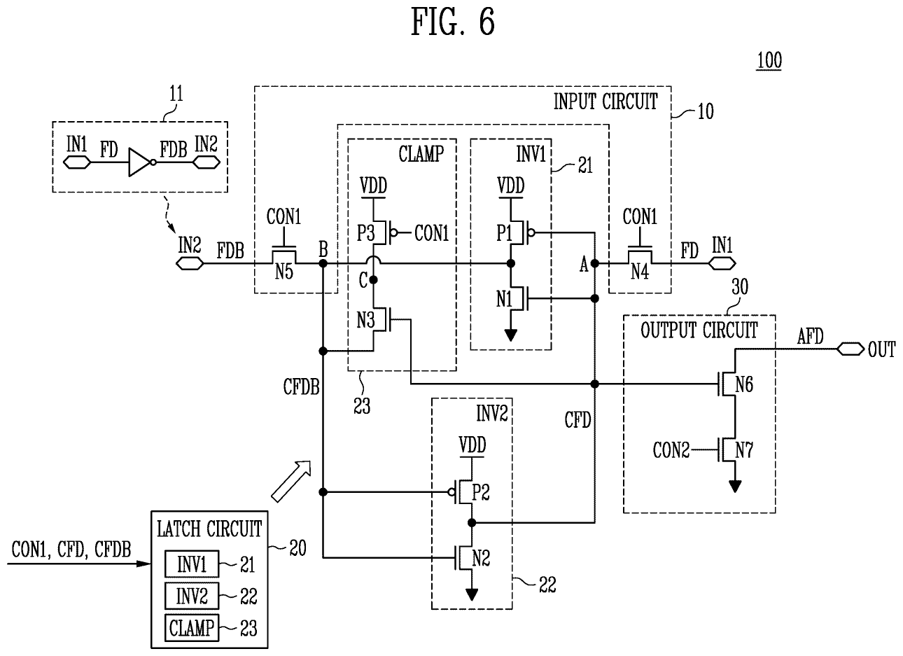

FIG. 6 is a diagram illustrating a detailed configuration of the fuse circuit 100 of FIG. 2 according to an embodiment of the present disclosure.

Referring to FIG. 6, the input circuit 10, the output circuit 30, and the first inverter 21 and the second inverter 22 included in the latch circuit 20 among the configurations of the fuse circuit are the same as that described with reference to FIG. 3. In FIG. 6, the latch circuit 20 may further include a clamp circuit 23.

The clamp circuit 23 may include a plurality of transistors connected in series between the power voltage node VDD and the second node B. The clamp circuit 23 may maintain the controlled fuse data inversion signal CFDB latched in the latch circuit 20 at a constant level, in response to the first control signal CON1 and the controlled fuse data signal CFD applied to the first node A. The clamp circuit 23 may maintain the controlled fuse data signal CFD at a constant level by maintaining the controlled fuse data inversion signal CFDB at a constant level.

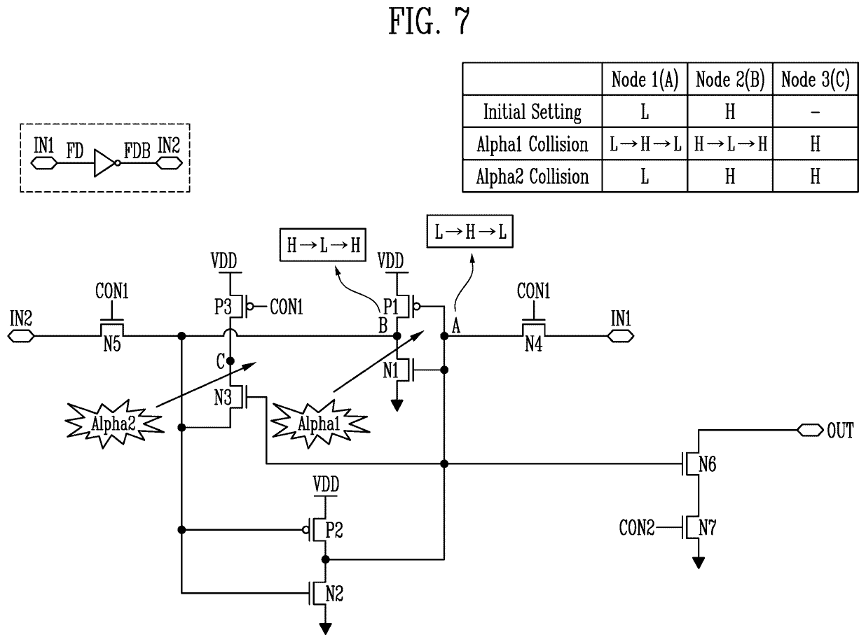

The clamp circuit 23 may include a third PMOS transistor P3 and a third NMOS transistor N3 connected in series between the power voltage node VDD and the second node B. The first control signal CON1 may be applied to a gate terminal of the third PMOS transistor P3, and a gate terminal of the third NMOS transistor N3 may be connected to the first node A. An operation of the clamp circuit 23 is described later with reference to FIG. 7.

FIG. 7 is a diagram illustrating soft error prevention in the fuse circuit 100 of FIG. 6.

Referring to FIG. 7, when the fuse data signal applied to the first input node IN1 has a low level L, the voltage signal of the first node A may be set to a low level L and the voltage signal of the second node B may be set to a high level H initially, in response to the first control signal CON1. After the controlled fuse data signal CFD is latched in the latch circuit, since the first control signal CON1 is deactivated and has a low level L, the third PMOS transistor P3 may be turned on, and a voltage signal of a third node C may transition to a high level H.

In an example of FIG. 7, the embodiment is described based on that the alpha particle collides with the first NMOS transistor N1. When the alpha particle collides with the first NMOS transistor N1, the first NMOS transistor N1 may be momentarily turned on. The second node B may be connected to the ground voltage node, and the voltage signal of the second node B may transition to a low level L.

When the voltage signal of the second node B transitions to a low level L, the second PMOS transistor P2 is turned on, and the voltage signal of the first node A transitions to a high level H.

When the voltage signal of the first node A transitions to a high level H, the third NMOS transistor N3 of the clamp circuit is turned on. Therefore, since both of the third PMOS transistor P3 and the third NMOS transistor N3 are turned on, the voltage signal of the second node B may transition from a low level L to a high level H again.

When the voltage signal of the second node B transitions to a high level H, since the second PMOS transistor P2 is turned off and the second NMOS transistor N2 is turned on, the voltage signal of the first node A transitions from a high level H to a low level L again.

When the voltage signal of the first node A transitions to a low level L, the third NMOS transistor N3 of the clamp circuit and the first NMOS transistor N1 of the first inverter circuit may be turned off.

In a case of the fuse circuit of FIG. 6, even though the alpha particle collides with the first NMOS transistor N1 due to the clamp circuit, the low level which is the initially set voltage signal of the first node A and the high level which is the voltage signal of the second node B may be maintained.

An embodiment of the present disclosure is described based on that the alpha particle collides with the third NMOS transistor N3. When the alpha particle collides with the third NMOS transistor N3, the third NMOS transistor N3 may be momentarily turned on. The voltage signal of the second node B may maintain a high level H because the third PMOS transistor P3 is turned on. In a similar method, the voltage signal of the first node A may maintain a low level L.

Therefore, a case where the alpha particle collides with the third NMOS transistor N3 does not affect the flip of the fuse data.

Compared to the configuration of the fuse circuit of FIG. 3, in a case of FIG. 6, due to the clamp circuit, even though the alpha particle is emitted to the fuse circuit and collides with the NMOS transistor, a fuse data signal level may be recovered to an original state, and thus the fuse circuit including the clamp circuit may have high reliability in relation to soft error.

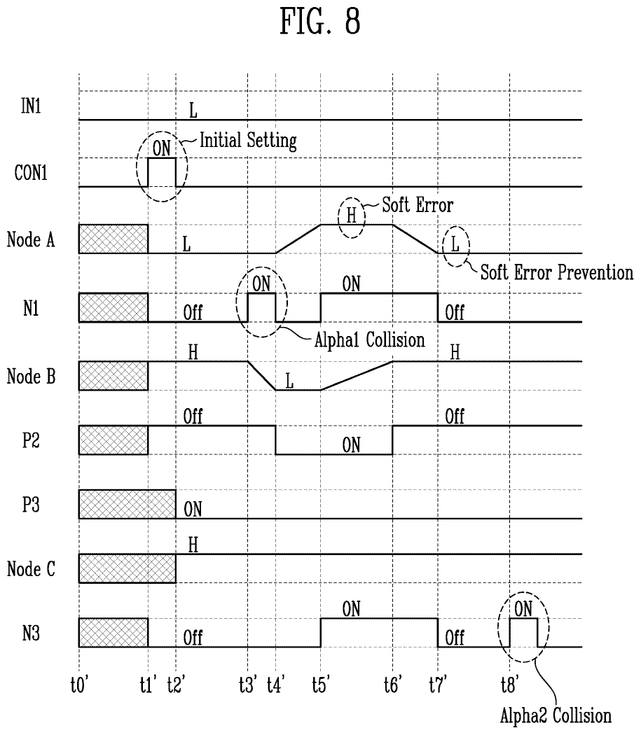

FIG. 8 is a timing diagram illustrating soft error prevention of FIG. 7.

Referring to FIG. 8, a soft error prevention operation of the fuse circuit in t0′ to t8′ may be described.

At t0′, the fuse data signal applied to the first input node IN1 may have a low level L.

At t1′, when the first control signal CON1 is activated, in response to the first control signal CON1, the voltage signal of the first node A may be set to a low level L and the voltage signal of the second node B may be set to a high level H initially. The low level L may be the ground voltage level and the high level H may be the power voltage level.

At t2′, when the first control signal CON1 is deactivated, the third PMOS transistor P3 may be turned on, and the voltage signal of the third node C may be set to a high level H.

At t3′, when the alpha particle collides with the first NMOS transistor N1, the first NMOS transistor N1 may be momentarily turned on. The second node B may be connected to the ground voltage node.

In t3′ to t4′, the voltage signal of the second node B may transition to a low level L.

At t4′, since the voltage signal of the second node B has a low level L, the second PMOS transistor P2 may be turned on. The first node A may be connected to the power voltage node.

In t4′ to t5′, the voltage signal of the first node A may transition to a high level H.

At t5′, since the voltage signal of the first node A has a high level H, the third NMOS transistor N3 may be turned on. Since both of the third PMOS transistor P3 and the third NMOS transistor N3 are turned on, the second node B may be connected to the power voltage node.

In t5′ to t6′, the voltage signal of the second node B may transition from a low level L to a high level H again.

At t6′, since the voltage signal of the second node B has a high level H, the second PMOS transistor P2 may be turned off and the second NMOS transistor N2 (not shown) may be turned on. The first node A may be connected to the ground voltage node.

In t6′ to t7′, the voltage signal of the first node A transitions from a high level H to a low level L again.

At t7′, since the voltage signal of the first node A has a low level L, the third NMOS transistor N3 of the clamp circuit and the first NMOS transistor N1 of the first inverter circuit may be turned off.

In the case of the fuse circuit of FIG. 6, even though the alpha particle collides with the first NMOS transistor N1 due to the clamp circuit, the low level which is the initially set voltage signal of the first node A and the high level which is the voltage signal of the second node B may be maintained.

At t8′, the alpha particle may collide with the third NMOS transistor N3, and thus the third NMOS transistor N3 may be momentarily turned on. Since the third PMOS transistor P3 is also turned on, the second node B may be connected to the power voltage node, and the voltage signal of the second node B may maintain a high level. Therefore, the collision of the alpha particle with the third NMOS transistor N3 may not affect the voltage signal of the second node B, and the voltage signal of the first node A may also maintain a low level.

While embodiments of the present disclosure have been shown and described with reference to certain embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described embodiments but should be determined by not only the appended claims but also the equivalents thereof.

Although specific terminologies are used here, those are only to describe the embodiments of the present disclosure. Therefore, the embodiments of the present disclosure are not restricted to the above-described embodiments and many variations are possible within the spirit and scope of the present disclosure. It should be apparent to those skilled in the art that various modifications can be made based on the technological scope of the present disclosure in addition to the embodiments disclosed herein. Furthermore, the embodiments may be combined to form additional embodiments.

What is claimed is:

1. A fuse circuit comprising:
an input circuit configured to transmit, to a first node, a fuse data signal applied to a first input node as a controlled fuse data signal and transmit, to a second node, a fuse data inversion signal applied to a second input node as a controlled fuse data inversion signal, in response to a first control signal; and
a latch circuit configured to latch the controlled fuse data signal and the controlled fuse data inversion signal,
wherein the latch circuit comprises:
a first inverter configured to receive the controlled fuse data signal from the first node and output the controlled fuse data inversion signal to the second node;
a second inverter configured to receive the controlled fuse data inversion signal from the second node and output the controlled fuse data signal to the first node; and
a clamp circuit coupled between a power voltage node and the second node, and configured to maintain the controlled fuse data signal of the first node at a constant level in response to the first control signal and a voltage signal of the first node.

2. The fuse circuit of claim 1, wherein the clamp circuit includes a third PMOS transistor and a third NMOS transistor connected in series between the power voltage node and the second node,
the first control signal is applied to a gate terminal of the third PMOS transistor, and
a gate terminal of the third NMOS transistor is connected to the first node.

3. The fuse circuit of claim 1, wherein the input circuit comprises:
an inverter inverting the fuse data signal and outputting the fuse data inversion signal;
a fourth NMOS transistor transmitting, to the first node, the fuse data signal as the controlled fuse data signal in response to the first control signal; and
a fifth NMOS transistor transmitting, to the second node, the fuse data inversion signal as the controlled fuse data inversion signal, in response to the first control signal.

4. The fuse circuit of claim 1, wherein the first inverter includes a first PMOS transistor connected between the power voltage node and the second node, and a first NMOS transistor connected between the second node and a ground voltage node, and
each of a gate terminal of the first PMOS transistor and a gate terminal of the first NMOS transistor is connected to the first node.

5. The fuse circuit of claim 1, wherein the second inverter includes a second PMOS transistor connected between the power voltage node and the first node, and a second NMOS transistor connected between the first node and a ground voltage node, and
each of a gate terminal of the second PMOS transistor and a gate terminal of the second NMOS transistor is connected to the second node.

6. The fuse circuit of claim 1, further comprising:
an output circuit configured to output, to an output node, the controlled fuse data signal received from the first node as an address processed fuse data signal, in response to a second control signal.

7. The fuse circuit of claim 6, wherein the output circuit includes a sixth NMOS transistor and a seventh NMOS transistor connected in series between the output node and a ground voltage node,
a gate terminal of the sixth NMOS transistor is connected to the first node, and
the second control signal is applied to a gate terminal of the seventh NMOS transistor.

8. A fuse circuit comprising:
a first node receiving a controlled fuse data signal in response to a first control signal;
a second node receiving a controlled fuse data inversion signal in response to the first control signal;
a first inverter including a first PMOS transistor connected between a power voltage node and the second node, and a first NMOS transistor connected between the second node and a ground voltage node, and configured to receive the controlled fuse data signal from the first node and output the controlled fuse data inversion signal to the second node;
a second inverter including a second PMOS transistor connected between the power voltage node and the first node, and a second NMOS transistor connected between the first node and the ground voltage node, and configured to receive the controlled fuse data inversion signal from the second node and output the controlled fuse data signal to the first node; and
a clamp circuit including a third PMOS transistor and a third NMOS transistor connected in series between the power voltage node and the second node,
wherein each of a gate terminal of the first PMOS transistor and a gate terminal of the first NMOS transistor is connected to the first node,
wherein each of a gate terminal of the second PMOS transistor and a gate terminal of the second NMOS transistor is connected to the second node, and
wherein the first control signal is applied to a gate terminal of the third PMOS transistor, and a gate terminal of the third NMOS transistor is connected to the first node.

9. The fuse circuit of claim 8, wherein, when the first NMOS transistor is turned on by an alpha particle collision at a first time point, a potential of the second node transitions from a power voltage level to a ground voltage level during from the first time point to a second time point,
when the second PMOS transistor is turned on at the second time point, a potential of the first node transitions from the ground voltage level to the power voltage level during the second time point to a third time point, and
when both of the third PMOS transistor and the third NMOS transistor are turned on at the third time point, the potential of the second node transitions from the ground voltage level to the power voltage level during the third time point to a fourth time point, and maintains the power voltage level.

10. A fuse circuit comprising:
a first node;
a second node;
a first inverter coupled between the first node and the second node and configured to receive a controlled fuse data signal through the first node, and invert the controlled fuse data signal to output the controlled fuse data inversion signal to the second node;
a second inverter coupled between the second node and the first node and configured to receive the controlled fuse data inversion signal through the second node, and invert the controlled fuse data inversion signal to output the controlled fuse data to the first node; and
a clamp circuit coupled between the first node and the second node and configured to maintain the controlled fuse data signal at a constant level by clamping a level of the controlled fuse data inversion signal.

11. The fuse circuit of claim 10, further comprising:
an input circuit configured to transmit, to the first node, a fuse data signal applied to a first input node as the controlled fuse data signal and transmit, to the second node, a fuse data inversion signal applied to a second input node as the controlled fuse data inversion signal, in response to a first control signal.

12. The fuse circuit of claim 11, wherein the first inverter includes
a first PMOS transistor coupled between a power voltage node and the second node, and
a first NMOS transistor coupled between the second node and a ground voltage node.

13. The fuse circuit of claim 12, wherein the second inverter includes
a second PMOS transistor coupled between the power voltage node and the first node, and
a second NMOS transistor coupled between the first node and the ground voltage node.

14. The fuse circuit of claim 13, wherein the clamp circuit includes
a third PMOS transistor and a third NMOS transistor coupled in series between the power voltage node and the second node.

15. The fuse circuit of claim 14, wherein each of a gate terminal of the first PMOS transistor and a gate terminal of the first NMOS transistor is coupled to the first node,
wherein each of a gate terminal of the second PMOS transistor and a gate terminal of the second NMOS transistor is coupled to the second node, and
a first control signal is applied to a gate terminal of the third PMOS transistor, and a gate terminal of the third NMOS transistor is coupled to the first node.

16. The fuse circuit of claim 15, wherein, when the first NMOS transistor is turned on by an alpha particle collision at a first time point, a potential of the second node transitions from a power voltage level to a ground voltage level during the first time point to a second time point,
when the second PMOS transistor is turned on at the second time point, a potential of the first node transitions from the ground voltage level to the power voltage level during the second time point to a third time point, and
when both of the third PMOS transistor and the third NMOS transistor are turned on at the third time point, the potential of the second node transitions from the ground voltage level to the power voltage level during the third time point to a fourth time point, and maintains the power voltage level.
